(19) United States
(12) Patent Application Publication
(10) Pub. No.: US 2026/0293057 A1
(43) Pub. Date: Sep. 24, 2026

(54) HEAT-DISSIPATION DEVICE WITH WEDGE-SHAPED CROSS SECTION

(71) Applicant: CARIAD SE, WOLFSBURG (DE)

(72) Inventors: Jeffrey Michael Dauber, Boulder Creek, CA (US); Alexander Dixon, Anselmo, CA (US)

(21) Appl. No.: 19/083,058

(22) Filed: Mar. 18, 2025

(51) Int. Cl. H05K 7/20

(52) U.S. Cl. CPC H05K 7/20445

(57) ABSTRACT

An apparatus is provided. The apparatus includes an electronic device having a first surface. The apparatus also includes a heat-dissipation device having a second surface and a third surface. An angle between the second surface and the third surface comprises a non-zero angle. The heat-dissipation device is removable from the apparatus. The apparatus further includes a thermal interface material disposed between the first surface and the second surface.

### TECHNICAL FIELD

Aspects of the present disclosure relate to a heat-dissipation device, and more particularly, to a heat-dissipation device with a wedge-shaped cross section.

### BACKGROUND

Computing devices/systems are more prevalent than ever and are often included in an ever-increasing number of devices. In addition, as the performance of the computing devices/systems increase, the amount of heat generated by the computing devices/systems increase. For example, as processing devices (e.g., central processing units (CPUs), graphics processing units (GPUs), etc.) and/or memory become faster (e.g., increase in processing speed/frequency), the amount of heat generated by the processing devices and/or memory may increase.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a block diagram that illustrates an example vehicle, in accordance with one or more embodiments of the present disclosure.

FIG. 2 is a diagram illustrating an example device enclosure, in accordance with one or more embodiments of the present disclosure.

FIG. 3 is a diagram illustrating an isometric view of an example heat-dissipation device, in accordance with some embodiments of the present disclosure.

FIG. 4 is a diagram illustrating a cross-sectional view of an example heat-dissipation device, in accordance with some embodiments of the present disclosure.

FIG. 5 is a diagram illustrating an isometric view of an example heat-dissipation device and an example heat source, in accordance with some embodiments of the present disclosure.

FIG. 6 is a diagram illustrating a cross-sectional view of an example heat-dissipation device and an example heat source, in accordance with some embodiments of the present disclosure.

FIG. 7 is a diagram illustrating a cross-sectional view of an example heat-dissipation device and two example heat sources, in accordance with some embodiments of the present disclosure.

FIG. 8 is a diagram illustrating a cross-sectional view of an example heat-dissipation device and two example heat sources, in accordance with some embodiments of the present disclosure.

FIG. 9 is a diagram illustrating shear force on thermal interface material when different heat-dissipation devices (e.g., a heatsink) are removed, in accordance with some embodiments of the present disclosure.

FIG. 10 is a diagram illustrating a top-down view of an example heat-dissipation device and an example retention mechanism, in accordance with some embodiments of the present disclosure.

FIG. 11 is a side view of a portion of an example heat-dissipation device, in accordance with some embodiments of the present disclosure.

FIG. 12 is a flow diagram of a method for installing a heat-dissipation device, in accordance with one or more embodiments of the present disclosure.

### DETAILED DESCRIPTION

As discussed above, as the performance of computing devices/systems increase, the amount of heat generated by the computing devices increase. For example, faster processing devices and/or faster memory (e.g., random-access memory, flash memory, etc.) may generate more heat when operating. If the temperature of a computing device/system increases and/or exceeds a threshold temperature (due to the heat generated by the processing devices and/or memory) the computing device/system may be damaged and/or may operate less efficiently (e.g., the number of operations performed by the computing device may be decreased to decrease the temperature).

Heat-dissipation devices are often used to decrease the amount of heat generated by components of a computer system/device. For example, a heat-dissipation device (e.g., a heatsink) may be used to decrease the amount of heat generated by a processing device. A heat-dissipation device may be removed for various reasons. For example, the heat-dissipation device may be removed to repair or check the operation of the processing device and/or other components in the computing device/system. Removing a heat-dissipation device may be a complicated, time-consuming, and/or costly task. For example, a thermal interface material (e.g., thermal grease, thermal pads, etc.) is often applied between the heat-dissipation device and the device/component that generates heat. Removing heat-dissipation device will often damage the thermal interface material, rendering the thermal interface material unusable. This may result in reapplication of new/additional thermal interface material, which increases the time, cost, complexity, etc., of removing and reinstalling the heat-dissipation device.

The embodiments, implementations, and/or examples, described provide a heat-dissipation device that has a wedge-shaped cross section. For example, a heat-dissipation device may have an upper surface and a lower surface that are not parallel to each other (e.g., have a non-zero angle), forming the wedge-shaped cross section. The wedge-shaped cross section may allow portions (or all) of the thermal interface material to be reused when the heat-dissipation device is removed, as discussed in more detail below. This may reduce the time, cost, complexity, etc., of removing and reinstalling the heat-dissipation device.

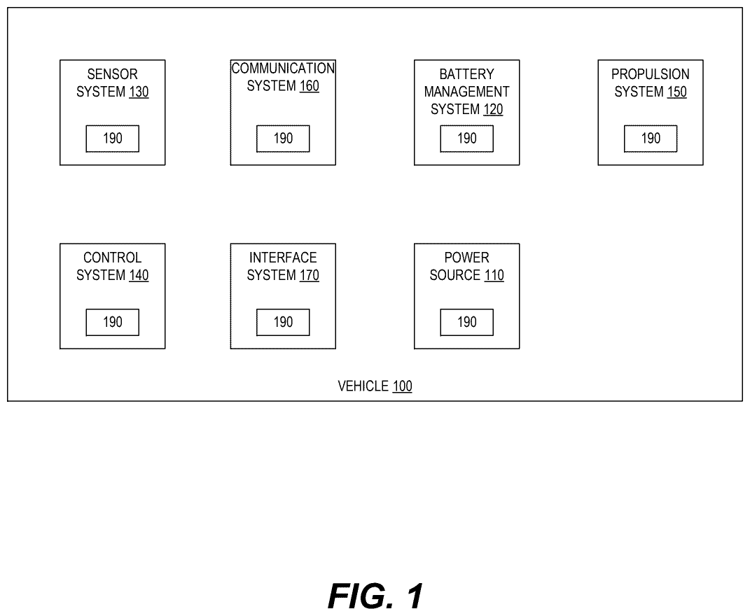

FIG. 1 is a block diagram that illustrates an example vehicle 100, in accordance with one or more embodiments of the present disclosure. In one embodiment, the vehicle 100 may be an autonomous vehicle (e.g., a self-driving vehicle). For example, the vehicle 100 may be a vehicle (e.g., car, truck, van, mini-van, semi-truck, taxi, drone, etc.) that may be capable of operating autonomously or semi-autonomously. In another embodiment, the vehicle 100 may also be a vehicle with autonomous capabilities. A vehicle with autonomous capabilities may be a vehicle that may be capable of performing some operations, actions, functions, etc., autonomously. For example, vehicle 100 may have adaptive cruise control capabilities and/or lane assist/keep capabilities. A vehicle 100 with autonomous capabilities may be referred to as a semi-autonomous vehicle.

The vehicle 100 may include various systems that allow the vehicle 100 to operate specific functions. For example, vehicle 100 includes a sensor system 130, a control system 140, a communication system 160, an interface system 170, a propulsion system 150, a power source 110, and a battery management system (BMS) 120. In other embodiments, the vehicle 100 may include more, fewer, and/or different systems, and each system may include more, fewer, and/or different components. Additionally, the systems and/or components may be combined and/or divided in any number/possibility of arrangements.

The power source 110 may be a source of energy that provides power (e.g., energy, electricity, etc.) to various components, modules, and/or systems of the vehicle 100. For example, the power source 110 may be used to power one or more of the sensor system 130, control system 140, communication system 160, interface system 170, propulsion system 150. Examples of power sources (e.g., energy sources) may include gasoline, diesel, propane, other compressed gas-based fuels, ethanol, solar panels, batteries, and other sources of electrical power. The power source 110 may be a combination of multiple power sources (e.g., may include any combination of fuel tanks, batteries, capacitors, and/or flywheels). In one embodiment, the power source 110 may be a battery (e.g., a lithium-ion battery, an electrical battery, etc.).

The BMS 120 may include various devices, systems, components, software, hardware, firmware, etc., that may monitor (e.g., detect, measure, etc.) the various characteristics of the power source 110. For example, if the power source 110 is a battery, the BMS 120 may monitor characteristics (e.g., operating parameters, conditions, etc.) such as battery temperature, battery voltage, battery current, battery charging and discharging data, state of charge of the power source 110, etc. The characteristics can be stored locally in the vehicle 100 by the BMS 120. The BMS 120 can also transmit such monitored information via the communication system 160 to other devices (e.g., to a server computer, to a cloud, etc.). The BMS 120 may also regulate the operating conditions of the power source 110. For example, the BMS 120 may cool the battery temperature to within a predefined threshold temperature. The BMS 120 may further manage, regulate, control, etc., the operation and/or usage of the power source 110.

The sensor system 130 may include one or more sensors (e.g., detectors, sensing elements, sensor devices, etc.). The one or more sensors may provide information about the operation of the vehicle 100, information about the condition of the vehicle 100, information about occupants/users of the vehicle 100, and/or information about the environment (e.g., a geographical area) where the vehicle 100 is located. The one or more sensors may be coupled to various types of communication interfaces (e.g., wired interfaces, wireless interfaces, etc.) to provide sensor data to other systems of the vehicle 100. For example, a sensor may be coupled to a storage device (e.g., a memory, a cache, a buffer, a disk drive, flash memory, etc.) and/or a computing device (e.g., a processor, an ASIC, an FPGA, etc.) via a control area network (CAN) bus (or other type of communication bus, such as a Flexray). In another example, a sensor may be coupled to a storage drive and/or a computing device via Bluetooth, Wi-Fi, etc. Examples of sensors may include, but are not limited to, tire pressure sensors, steering sensors (e.g., to determine the positions/angles of one or more wheels), a compass, temperature sensors, a global positioning system (GPS) receiver/sensor, a light detection and ranging (LIDAR) device/sensor, an ultrasonic device/sensor, a camera (e.g., a video camera), a radar device/sensor, etc.

The control system 140 may include hardware, software, firmware, or a combination thereof that may control the functions, operations, actions, etc., of the vehicle 100. For example, the control system 140 may be able to control a braking system and/or an engine to control the speed and/or acceleration of the vehicle 100. In another example, the control system 140 may be able to control a steering system to turn the vehicle 100 left or right. In a further example, the control system 140 may be able to control the headlights or an all-wheel drive (AWD) system of the vehicle 100 based on weather/driving conditions (e.g., if the environment has snow/rain, if it is nighttime in the environment, etc.). The control system 140 may use sensor data and/or outputs generated by machine learning models to control the vehicle 100.

The control system 140 may use outputs generated one or more machine learning models to control the vehicle. For example, control system 140 may generate one or more steering commands based on the outputs of a machine learning model (e.g., based on objects detected by a machine learning model). The steering command may indicate the direction that a vehicle 100 should be turned (e.g., left, right, etc.) and may indicate the angle of the turn. The control system 140 may actuate one or more mechanisms/systems (e.g., a steering system, a steering wheel, etc.) to turn the vehicle 100 (e.g., to control the vehicle 100) based on the steering command. For example, the control system 140 may actuate one or more steering mechanisms that may turn/move the wheels of the vehicle by a certain number of degrees to steer the vehicle 100. The control system 140 may also control acceleration and/or deceleration of the vehicle 100. For example, the control system 140 may use the accelerator to speed up the vehicle 100 or may use the brake to slow down the vehicle 100.

The propulsion system 150 may include various devices, systems, components, software, hardware, firmware, etc., that may be used to move the vehicle 100. For example, the propulsion system 150 may include an engine/motor, an energy source, a transmission, and wheels/tires. The engine/motor may include any combination of an internal combustion engine, an electric motor (that can be powered by an electrical battery, fuel cell, and/or other energy storage device), and/or a steam engine.

The communication system 160 may include various devices, systems, components, software, hardware, firmware, etc., that allow the vehicle 100 to communicate (e.g., transmit and/or receive data) with various networks (e.g., computer networks, communication networks, etc.) and/or devices (e.g., other vehicles, server computers, etc.). For example, the communication system 160 may include antennas, network interfaces, wireless network interfaces (e.g., cellular, Wi-Fi, Bluetooth, ZigBee, ZWave, and/or other network interfaces). The communication system 160 may also allow the vehicle 100 to communicate with other vehicles (e.g., V2V communications), with infrastructure (e.g., V2I communications), and/or with other devices/networks (e.g., V2X communications).

The interface system 170 may include various devices, systems, components, software, hardware, firmware, etc., that allow the vehicle 100 to interact with external sensors, other vehicles, external computing devices, and/or a user. For example, the interface system 170 may include buttons, knobs, dials, touch screens, microphones, cameras, and/or other devices that interact with a user, present information to a user, receive user input from a user, etc. The interface system 170 may include displays (e.g., screens, liquid crystal displays, touchscreens, etc.) that may be used to present (e.g., display, show, etc.) content, information, data, etc., to a user.

One or more of the power source 110, the BMS 120, the sensor system 130, the control system 140, the propulsion system 150, the communication system 160, and the interface system 170 may include a computing system 190. The computing system 190 may include hardware such as processing devices (e.g., processors, central processing units (CPUs), processing cores, graphics processing units (GPUS)), memory (e.g., random access memory (RAM), storage devices (e.g., hard-disk drive (HDD), solid-state drive (SSD), memory chips, flash chips, etc.), and other hardware devices (e.g., sound card, video card, etc.). The computing system 190 may perform various tasks, operations, functions, actions, etc., for the various systems of the vehicle 100.

As illustrated in FIG. 1, each of the systems/components of the vehicle 100 includes a computing system 190. The computing system 190 may be referred to as a computing device, electronic device, etc. The computing system 190 may perform various tasks, operations, actions, functions, etc., for the systems/components of the vehicle 100. For example, the computing system 190 in the sensor system 130 may receive, process, and/or analyze sensor data. In another example, the computing system 190 in the communication system 160 may send and/or receive messages to other devices (e.g., a server computer). Each computing system 190 may include one or more heat sources (e.g., a processing device, a memory device, an electronic device, etc.) that may generate heat and one or more heat-dissipation devices to dissipate the heat generated by the one or more heat sources, as discussed in more detail below.

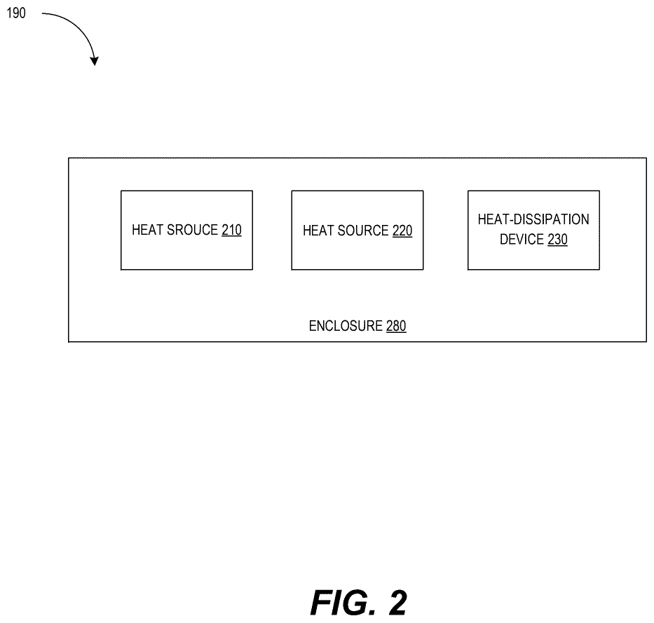

FIG. 2 is a block diagram that illustrates an example computing system 190, in accordance with one or more embodiments of the present disclosure. As discussed above, the computing system 190 may be included in various systems/components of a vehicle (e.g., may be included in one or more of the systems of vehicle 100 illustrated in FIG. 1) and/or other devices (e.g., server computers, networking devices, etc.). The computing system 190 includes a heat source 210, a heat source 220, and a heat-dissipation device 230.

In one embodiment, the heat source 210, heat source 220, and the heat-dissipation device 230 may be located within an enclosure 280. The enclosure 280 may be a structure, cage, chassis, frame, body, etc. The enclosure 280 may be full enclosed (e.g., each face of the enclosure 280 may be prevent access to the interior of the enclosure 280 or may be partially enclosed (e.g., the interior of the enclosure 280 may be accessible from one or more faces/edges of the enclosure 280).

The heat source 210 may a device/component that generates heat while in operation (e.g., while performing functions, tasks, operations, while operating, etc.). For example, the heat source 201 may be a printed circuit board (PCB) that includes a processing device (e.g., a processor, a central processing unit, a field programmable gate array (FPGA), an application specific integrated circuit (ASIC), a system-on-chip (SOC), a graphics processing unit (GPU), etc.), a memory device (e.g., a memory chip, a flash chip, etc.), etc. The processing device may generate or emit heat while in operation. For example, the processing device may become hotter (e.g., emit heat) as the processing device performs various functions, operations, tasks, etc. In another example, the heat source 210 may be an electronic device that includes devices/components that generate heat (e.g., an electronic device that includes a PCB and a processing device). Heat source 220 may be similar to heat source 210 (e.g., may a device/component that generates heat while in operation). In some embodiments, heat source 220 may be an optional component of the computing system 190.

The heat-dissipation device 230 may be a device that absorbs the heat generated the heat source 210 and/or heat source 220 and may distribute the heat to the surrounding environment and/or another component. The heat-dissipation device 230 may be referred to as a heatsink, a heat exchanger, a heat exchange device, a heat transfer device, a radiator, a dissipater, a thermal transfer device, a thermal exchange device, etc. The heat-dissipation device 230 may have a wedge-shaped cross section, as discussed in more detail below. The wedge-shaped cross section may allow portions (or all) of a thermal interface material to be reused when the heat-dissipation device 230 is removed, as discussed in more detail below.

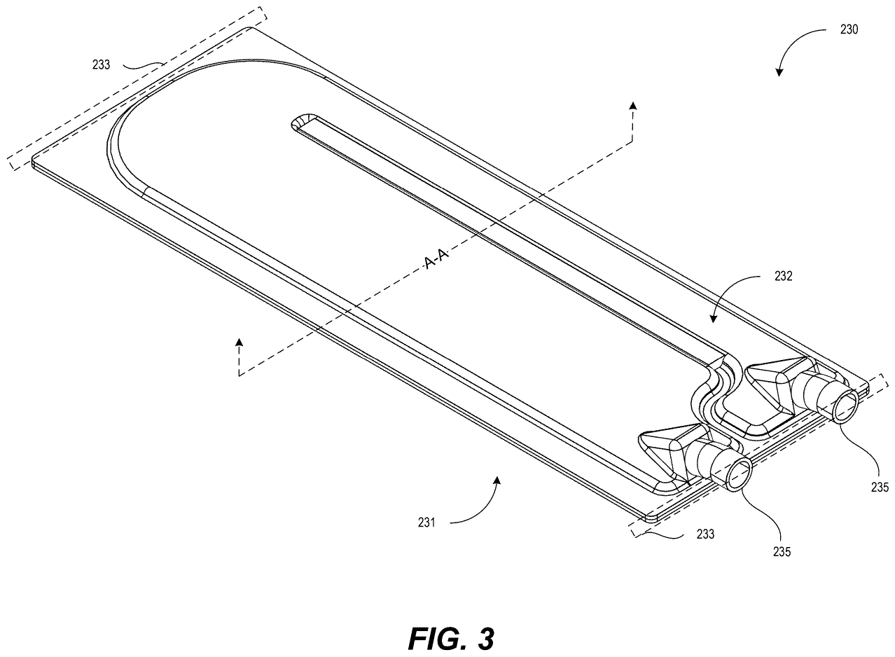

FIG. 3 is a diagram illustrating an isometric view of an example heat-dissipation device 230, in accordance with some embodiments of the present disclosure. As discussed above, the heat-dissipation device 230 may dissipate heat that is generated by one or more other devices/components. For example, the heat-dissipation device 230 may absorb the heat generated by one or more other devices/components and may distributing the heat to the surrounding environment and/or another component.

The heat-dissipation device 230 includes a surface 231 (e.g., a bottom/lower surface which is not visible in FIG. 3) and a surface 232 (e.g., an upper/top surface). The surface 231 may touch (e.g., come in contact with, interface with, abut, etc.) a first heat source (e.g., a first computing device/component, such as a processing device, processor, etc.) when the heat-dissipation device is inserted and/or installed in an enclosure (e.g., enclosure 280 illustrated in FIG. 2). The surface 232 may touch (e.g., come in contact with, interface with, abut, etc.) a second heat source (e.g., a second computing device/component, such as a processing device, processor, etc.) when the heat-dissipation device 230 is inserted and/or installed in the enclosure.

In one embodiment, one or more of the surface 231 and the surface 232 may dissipate heat (e.g., absorb heat or thermal energy from devices/components and disperse/dissipate the heat) that is absorbed from other devices/components via a thermal interface material (TIM). For example, thermal-interface material may be disposed, located, deposited, applied, etc., between the surface 231 and a first device/component (e.g., a surface of the first device/component). In another example, thermal-interface material may be disposed, located, deposited, applied, etc., between the surface 232 and a second device/component (e.g., a surface of the second device/component). A thermal interface material may be a material, substance, compound, etc., that is applied between the heat-dissipation device 230 and/or another device/component. The thermal interface material may enhance the thermal coupling/conductivity between the heat-dissipation device 230 and others devices/components. Examples of thermal interface material may include, but are not limited to, thermal tapes, thermal greases, dielectric pads, gap fillers, thermal conductive pads, solder, etc.

In one embodiment, the heat-dissipation device 230 includes alignment mechanisms 233. For example, the alignment mechanisms 233 may be the outer edges of the heat-dissipation device 230 (as illustrated by the dashed boxes). The alignment mechanisms 233 may guide, direct, align, etc., the heat-dissipation device 230 with other devices/components when during insertion, installation, removal, etc., of the heat-dissipation device. For example, the alignment mechanisms 233 may interface with other alignment mechanisms (e.g., grooves, slots, rails, etc.) in an enclosure where the heat-dissipation device 230 and/or other devices/components are located, as discussed in more detail below. The alignment mechanisms 233 may be referred to as edges, protrusions, tabs, etc. Although edges/protrusions and grooves/slots are discussed herein, various other types of alignment mechanisms or features may be used. For example, holes, apertures, bars, rods, plates, slides, wheels, gears, motors/actuators, etc., may be used to align the heat-dissipation device 230 with other devices/components, as discussed in more detail below.

The heat-dissipation device 230 also includes connectors 235. Connectors 235 may be connected to tubes or other components capable of providing a fluid, such as a coolant, to the heat-dissipation device 230. The heat-dissipation device 230 may use the coolant to distribute heat (absorbed from another device/component) to another area or device. For example, the connectors 235 may be connected to tubes that are connected to a coolant loop. The coolant loop may move coolant between the heat-dissipation device and a radiator (e.g., a radiator that is separate from the heat-dissipation device 230). The coolant may absorb heat from the heat-dissipation device 230. A pump (e.g., a liquid/water pump) may move the coolant (or other fluid) between the radiator (and the heat-dissipation device 230. The radiator may be coupled to a fan that may decrease the temperature (e.g., may cool) the coolant and the pump may provide the coolant back to the heat-dissipation device 230. In another example, the heat-dissipation device 230 may include fluid carrying channels (e.g., tubes) which may carry coolant to portions of the heat-dissipation device 230.

In one embodiment, an angle formed by the surface 231 and the surface 232 may be a non-zero angle. For example, the surface 231 and the surface 232 may not be parallel and the angle between the surface 231 and the surface 232 may be greater than zero (e.g., may be a non-zero angel). The non-zero angle between the surface 231 and the surface 230 may result in and/or may form a wedge-shaped cross section, as discussed in more detail below.

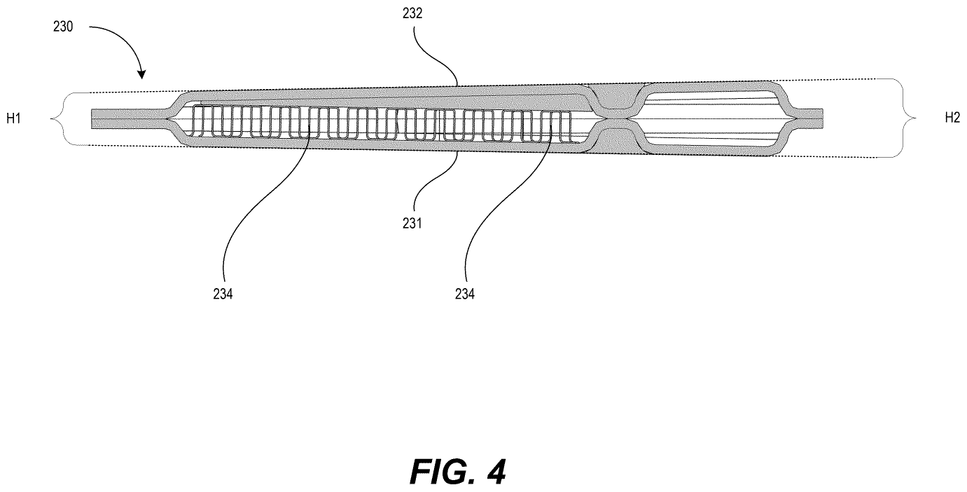

FIG. 4 is a diagram illustrating a cross-sectional view of an example heat-dissipation device 230, in accordance with some embodiments of the present disclosure. The cross-sectional view of heat-dissipation device 230 may be along the line A-A illustrated in FIG. 3. As discussed above, the heat-dissipation device 230 (e.g., a heatsink) may dissipate heat that is generated by one or more other devices/components.

The heat-dissipation device 230 includes a surface 231 (e.g., a bottom/lower surface) and a surface 232 (e.g., an upper/top surface). The surface 231 may interface with (e.g., touch, abut, contact, etc.) a first heat source when the heat-dissipation device 230 is inserted and/or installed in an enclosure (e.g., enclosure 280 illustrated in FIG. 2). The surface 232 may (optionally) interface with (e.g., touch, abut, contact, etc.) a second heat source when the heat-dissipation device is inserted and/or installed in the enclosure. As discussed above, one or more of the surface 231 and the surface 232 may dissipate heat that is absorbed from other devices/components via a thermal interface material. The thermal-interface material may be disposed, located, deposited, applied, etc., between the surface 231 and a first device/component, and/or may be disposed, located, deposited, applied, etc., between the surface 232 and a second device/component,

As illustrated in FIG. 4, the heat-dissipation device 230 includes fins 234 that are located within the heat-dissipation device 230 (e.g., are located internally, are located between surface 231 and surface 232, etc.). The fins 234 may provide additional surface area for dispersing/dissipating heat absorbed by the heat-dissipation device 230. Although fins 234 are illustrated in FIG. 4, other internal structures/components may be included in the heat-dissipation device 230. For example, heat dissipation device 230 may be solid (e.g., a solid piece of metal such as copper or aluminum). In another example, the heat-dissipation device 230 may include a vapor chamber.

As discussed above, the angle formed by the surface 231 and the surface 232 may be a non-zero angle. For example (as illustrated by the dashed lines), the surface 231 and the surface 232 may not be parallel with each other. The non-zero angle between the surface 231 and the surface 232 may result in and/or may form a wedge-shaped cross section as illustrated in FIG. 4. For example, the heat-dissipation device 230 has a wedge-shaped cross section because the height of the heat-dissipation device 230 on the left side of FIG. 4 (height H1) is smaller than the height of the heat-dissipation device 230 on the right side of FIG. 4 (height H2).

In one embodiment, the non-zero angle between the surface and the surface 232 may reduce an amount of shear or shear force that is exerted on the thermal interface material when the heat-dissipation device is removed from the enclosure, as discussed in more detail below. This may allow at least portions of the thermal interface material (if not all of the thermal interface material) to be reused when the heat-dissipation device 230 is reinserted or reinstalled in the enclosure, as discussed in more detail below.

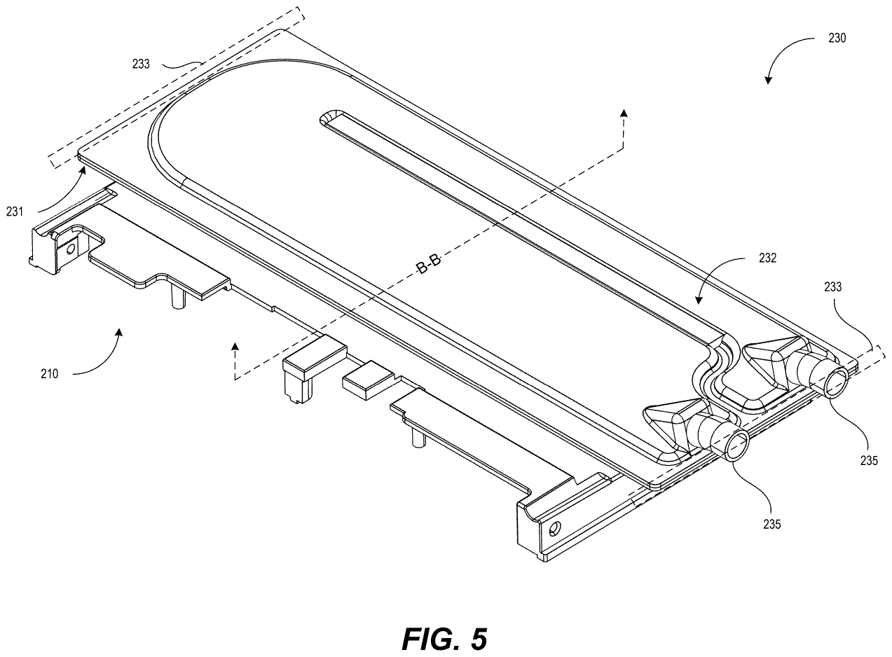

FIG. 5 is a diagram illustrating an isometric view of an example heat-dissipation device 230 (e.g., a heatsink) and an example heat source 210, in accordance with some embodiments of the present disclosure. As discussed above, the heat source 210 may be a device/component that generates heat. For example, the heat source 210 may be a printed circuit board (PCB) that includes a processing device, a memory device, etc. The processing device may generate or emit heat while in operation. For example, the processing device may become hotter as the processing device performs various functions, operations, tasks, etc.

The heat-dissipation device 230 may dissipate heat that is generated by the heat source 210. As discussed above, the heat-dissipation device 230 includes a surface 231 (which is not visible in FIG. 5) and a surface 232. The surface 231 may touch (e.g., come in contact with, interface with, abut, etc.) the heat source 210 (e.g., a first computing device/component, such as a processing device, processor, etc.) when the heat-dissipation device is inserted and/or installed in an enclosure (e.g., enclosure 280 illustrated in FIG. 2). The surface 231 may absorb heat or thermal energy from the heat source 210 via a thermal interface material and may disperse/dissipate the heat. The thermal-interface material (e.g., thermal tapes, thermal greases, etc.) may be disposed, located, deposited, applied, etc., between the surface 231 the heat source 210 (e.g., between the surface 231 and a surface of the heat source 210).

In one embodiment, the heat-dissipation device 230 includes alignment mechanisms 233. The alignment mechanisms 233 may guide, direct, align, etc., the heat-dissipation device 230 with other devices/components when during insertion, installation, removal, etc., of the heat-dissipation device, as discussed in more detail below. The heat-dissipation device 230 may be in an inserted/installed/attached configuration (e.g., an arrangement, a position, etc.).

The heat-dissipation device 230 also includes connectors 235. Connectors 235 may be connected to tubes or other components (e.g., a coolant loop that may include a pump and a radiator) capable of providing a fluid (e.g., a coolant) to the heat-dissipation device 230. The heat-dissipation device 230 may use the coolant to distribute heat (absorbed from another device/component) to another area or device (e.g., a radiator).

In one embodiment, an angle formed by the surface 231 and the surface 232 may be a non-zero angle. The non-zero angle between the surface 231 and the surface 232 may result in and/or may form a wedge-shaped cross section. The non-zero angle between the surface 231 and the surface 232 may reduce the amount of shear or shear force on the thermal interface material when the heat-dissipation device 230 is removed from the enclosure, as discussed in more detail below. Because the shear or shear force on the thermal interface material is reduced, portions (or all) of the thermal interface material may be reusable when the heat-dissipation device 230 is reinserted or reinstalled in the enclosure. For example, additional thermal interface material may not be needed when the heat-dissipation device 230 is reinserted or reinstalled in the enclosure.

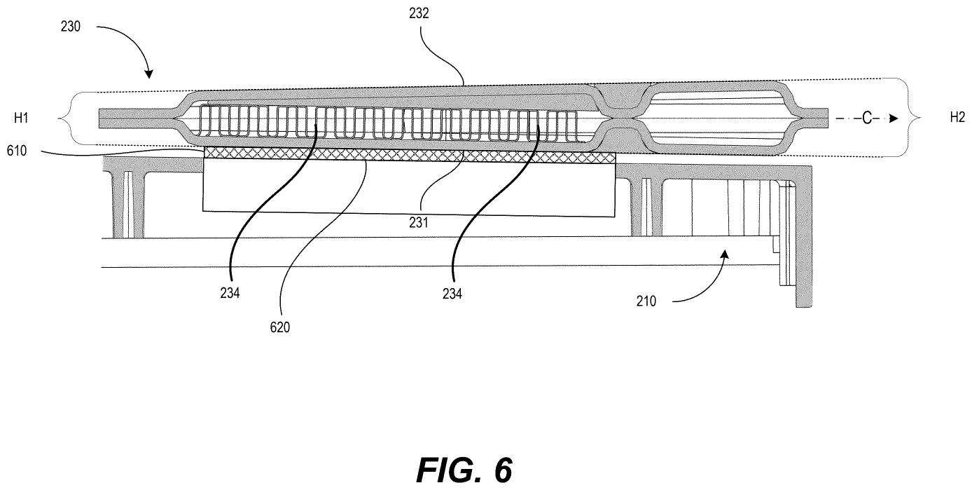

FIG. 6 is a diagram illustrating a cross-sectional view of an example heat-dissipation device 230 (e.g., a heatsink) and an example heat source 210, in accordance with some embodiments of the present disclosure. The heat-dissipation device 230 may be in an inserted/installed/attached configuration (e.g., an arrangement, a position, etc.). As discussed above, the heat source 210 may be a device/component that generates heat. The heat-dissipation device 230 may dissipate heat that is generated by the heat source 210. The heat-dissipation device 230 includes a surface 231 and a surface 232. The surface 231 may touch the heat source 210 when the heat-dissipation device is inserted and/or installed in an enclosure (e.g., enclosure 280 illustrated in FIG. 2). For example, the surface 231 may be in contact with and/or parallel to the surface 620. The surface 231 may absorb heat or thermal energy from the heat source 210 via a thermal interface material 610 and may disperse/dissipate the heat. The thermal-interface material 610 (e.g., thermal tapes, thermal greases, etc.) may be disposed, located, deposited, applied, etc., between the surface 231 the heat source 210 (e.g., between the surface 231 and surface 620 of the heat source 210).

In one embodiment, an angle formed by the surface 231 and the surface 232 may be a non-zero angle. The non-zero angle between the surface 231 and the surface 232 may result in and/or may form a wedge-shaped cross section, as illustrated by the dashed lines and by the heights H1 and H2. The non-zero angle between the surface 231 and the surface 232 may reduce the amount of shear or shear force on the thermal interface material 610 when the heat-dissipation device 230 is removed from the enclosure.

In one embodiment, the amount of shear or shear force on the thermal interface material 610 may be reduced when the heat-dissipation device is removed (and/or inserted) along a plane C. The plane C is illustrated as a dotted and dashed line in FIG. 6 because the cross-sectional view of the heat-dissipation device 230 is perpendicular to the plane C. Plane C may bisect the angle formed by/between the surface 231 and the surface 232. For example, plane C may have an angle of 0 degrees. The surface 232 may have an angle of X degrees and the surface 231 may have an angle of −X degrees. The angle formed by the surface 231 and 232 may be 2*X. Because the heat-dissipation device 230 is removed and/or inserted inline with the plane C and the plane C is not parallel to the surface 231 and/or 620, the amount of shear or shear force on the thermal interface material 610 is reduced. In particular, the amount of shear or shear force is reduced when compared to a scenario where the heat-dissipation device 230 is removed along a plane that is parallel to the surface 620. This allows some (if not all) of the thermal interface material 610 to be reusable when the heat-dissipation device 230 is reinserted or reinstalled.

In one embodiment, one or more alignment mechanisms (e.g., tabs, protrusions, grooves, slots, etc.) on the heat-dissipation device 230 and/or the enclosure may allow the heat-dissipation device to be removed along the plane C. For example, tabs on the heat-dissipation device 230 may be aligned with grooves/slots on the enclosure such that the heat-dissipation device 230 is inserted/removed along the plane C.

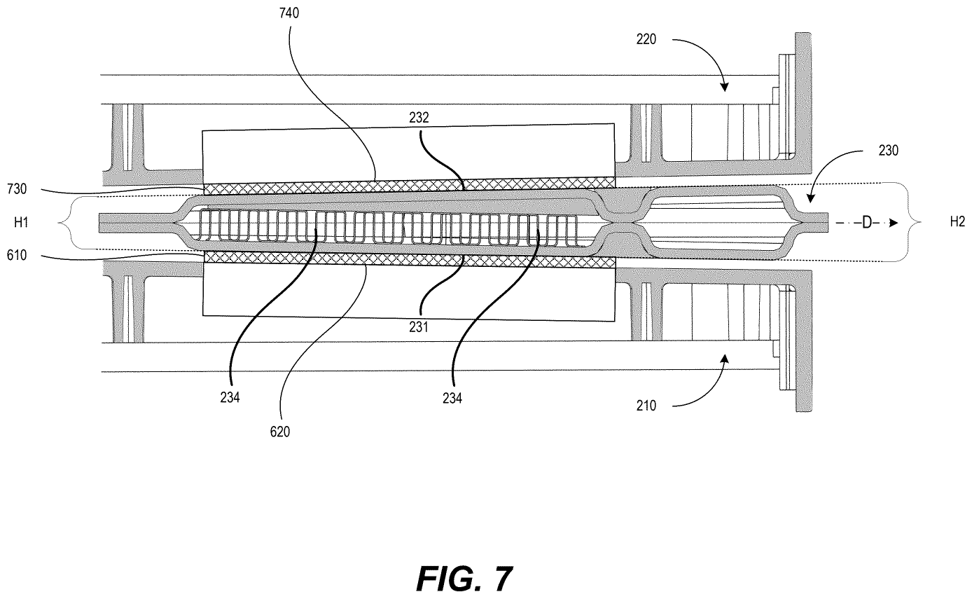

FIG. 7 is a diagram illustrating a cross-sectional view of an example heat-dissipation device 230 (e.g., a heatsink) and two example heat sources 210 and 220, in accordance with some embodiments of the present disclosure. The heat-dissipation device 230 may be in an inserted/installed/attached configuration (e.g., an arrangement, a position, etc.). As discussed above, the heat source 210 may be a device/component that generates heat and heat source 220 may also be a device/component that generates heat. The heat-dissipation device 230 may dissipate heat that is generated by the heat sources 210 and 220. As discussed above, the heat-dissipation device 230 includes a surface 231 and a surface 232. The surface 231 may touch and/or may be in planar alignment with the heat source 210 when the heat-dissipation device is inserted and/or installed in an enclosure. For example, the surface 231 may be in contact with and/or parallel to the surface 620. The surface 231 may absorb heat or thermal energy from the heat source 210 via a thermal interface material 610 and may disperse/dissipate the heat. The surface 232 may be in contact with and/or may be in planar alignment with the heat source 220 when the heat-dissipation device 230 is inserted and/or installed in an enclosure. For example, the surface 232 may be in contact with and/or parallel to the surface 740. The surface 232 may absorb heat or thermal energy from the heat source 220 via a thermal interface material 730 and may disperse/dissipate the heat.

In one embodiment, surface 740 (of heat source 220) and surface 620 (of heat source 210) may also form an angle. The angle between the surface 740 and the surface 620 may be the same, or within a threshold of, the angle formed by surface 231 and surface 232. Having the same angle between the surface 740 and the surface 620 and between the surface 231 and surface 232 allows for better fitment of the heat-dissipation device 230 which may allow for better heat transfer to the heat-dissipation device 230.

As discussed above, the angle formed by the surface 231 and the surface 232 may be a non-zero angle. The non-zero angle between the surface 231 and the surface 232 may result in and/or may form a wedge-shaped cross section, as illustrated by the dashed lines and by the heights H1 and H2. The non-zero angle between the surface 231 and the surface 232 may reduce the amount of shear or shear force on the thermal interface material 610 when the heat-dissipation device 230 is removed from the enclosure.

In one embodiment, the amount of shear or shear force on the thermal interface material 610 may be reduced when the heat-dissipation device is removed (and/or inserted) along a plane D. The plane D is illustrated as a dotted and dashed line in FIG. 7 because the cross-sectional view of the heat-dissipation device 230 is perpendicular to plane D. Because the heat-dissipation device 230 is removed and/or inserted in line with the plane D, and the plane D is not parallel to the surface 231 and is not parallel to the surface 620, the amount of shear or shear force on the thermal interface material 610 is reduced. In addition, because the plane D is not parallel to the surface 232 and is not parallel to the surface 740, the amount of shear or shear force on the thermal interface material 730 is reduced. This allows some (if not all) of the thermal interface material 610 and/or 730 to be reusable when the heat-dissipation device 230 is reinserted or reinstalled.

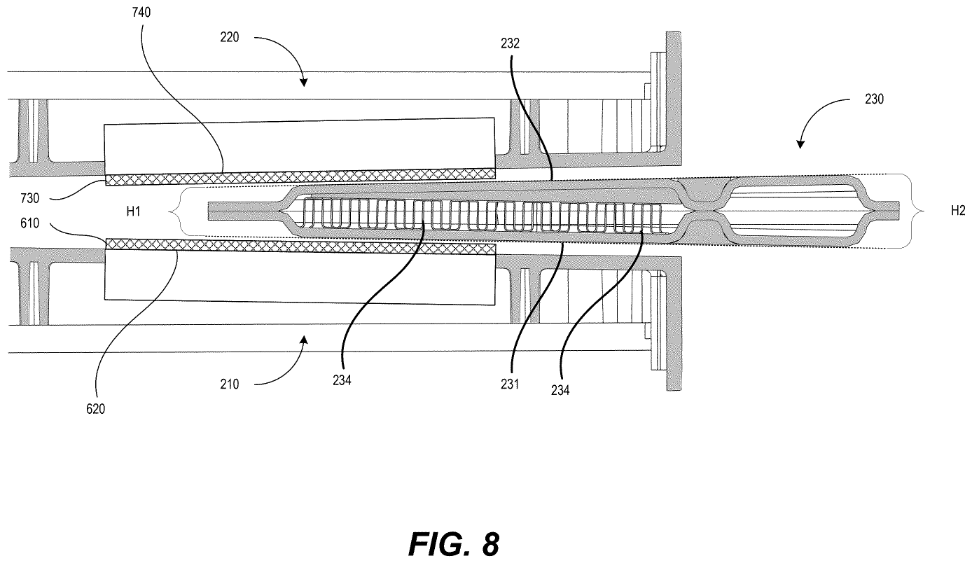

FIG. 8 is a diagram illustrating a cross-sectional view of an example heat-dissipation device 230 (e.g., a heatsink) and two example heat sources 210 and 220, in accordance with some embodiments of the present disclosure. As discussed above, the heat source 210 may be a device/component that generates heat and heat source 220 may also be a device/component that generates heat. The heat-dissipation device 230 may dissipate heat that is generated by the heat sources 210 and 220. The heat-dissipation device 230 includes a surface 231 and a surface 232.

As discussed above, the angle formed by the surface 231 and the surface 232 may be a non-zero angle. The non-zero angle between the surface 231 and the surface 232 may result in and/or may form a wedge-shaped cross section, as illustrated by the dashed lines and by the heights H1 and H2. Surface 740 (of heat source 220) and surface 620 (of heat source 210) may also form an angle. The angle between the surface 740 and the surface 620 may be the same, or within a threshold of, the angle formed by surface 231 and surface 232.

In one embodiment, the heat-dissipation device 230 may be in a detached/uninstalled/removed configuration. For example, referring to FIG. 7, the heat-dissipation device 230 has been moved towards the left along the plane D. The amount of shear or shear force on the thermal interface material 610 may be reduced when the heat-dissipation device is removed along the plane D illustrated in FIG. 7. Because the heat-dissipation device 230 is removed in line with the plane D and the plane D is not parallel to the surface 231 and is not parallel to the surface 620, the amount of shear or shear force on the thermal interface material 610 is reduced. In addition, because the plane D is not parallel to the surface 232 and is not parallel to the surface 740, the amount of shear or shear force on the thermal interface material 730 is reduced. This allows some (if not all) of the thermal interface material 610 and/or 730 to be reusable when the heat-dissipation device 230 is reinserted or reinstalled.

Although examples/embodiments disclosed herein may refer to inserting/removing the heat-dissipation device 230 along a plane that bisects the angle formed by/between the surface 231 and the surface 232 (e.g., along planes C and D), the heat-dissipation device 230 may be removed along other planes in other embodiments. For example, if the plane C/D has an angle of 0 degrees, the heat-dissipation device 230 may be inserted/removed along a plane has a greater angle than plane C/D (e.g., a positive angle), or may be inserted/removed along a plane has a smaller angle than plane C/D (e.g., a negative angle).

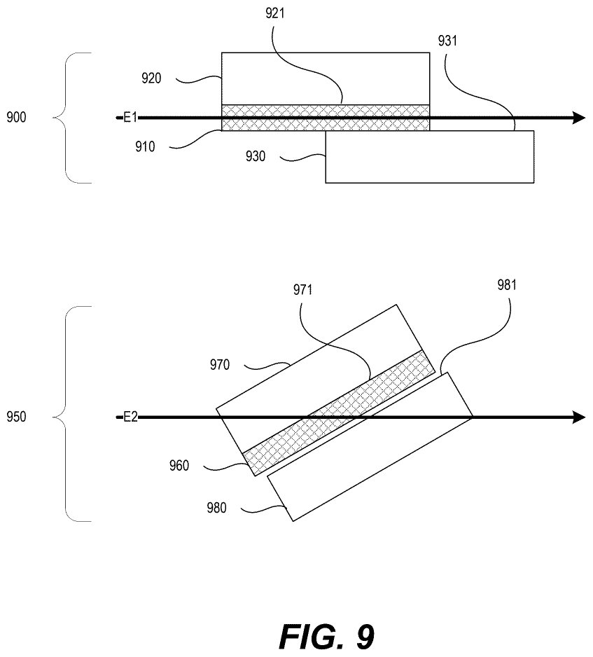

FIG. 9 is a diagram illustrating shear force on thermal interface material when different heat-dissipation devices (e.g., heatsinks) are removed, in accordance with some embodiments of the present disclosure. Two computing systems 900 and 950 are illustrated.

Computing system 900 includes a heat source 920, thermal interface material 910, and a heat-dissipation device 930. The thermal interface material 910 is located/disposed between the surface 921 (of the heat source) and the surface 931 (of the heat-dissipation device. The removal of heat-dissipation device 930 is illustrated by the arrow E1. In particular, the heat-dissipation device 930 is removed in the direction illustrated by the arrow E1. Because the heat-dissipation device 930 is removed in a direction that is parallel to the surfaces 921 and 931, a shear force is applied on the thermal interface material 910 during the entire time that the heat-dissipation device 930 is being removed. This may result in more stress, stretching, deformation, damage, strain, etc., to the thermal interface material 910. When too much deformation or damage has occurred in the thermal interface material 910, the thermal interface material 910 may not be reusable. For example, if there is too much damage to the thermal interface material 910, the thermal interface material 910 may need to be removed. This may increase the amount of time, the cost, and/or complexity for removing the heat-dissipation device 930. For example, if the heat source 920 (e.g., a computing device) needs to be serviced (e.g., fixed, repaired, replaced, etc.) or diagnosed, reapplying the thermal interface material may increase the time, cost, and/or complexity of the process.

Computing system 950 includes a heat source 970, thermal interface material 960, and a heat-dissipation device 980. The thermal interface material 960 is located/disposed between the surface 971 (of the heat source) and the surface 981 (of the heat-dissipation device. The removal of heat-dissipation device 980 is illustrated by the arrow E1. In particular, the heat-dissipation device 980 is removed in the direction illustrated by the arrow E1. Because the heat-dissipation device 980 is removed in a direction that is not parallel to the surfaces 971 and 981, a shear force is applied on the thermal interface material 960 for a smaller period of time (as compared to computing system 900) when the heat-dissipation device 980 is being removed. This may result in less stress, less stretching, less deformation, less damage, less strain, etc., to the thermal interface material 960. In particular, the heat-dissipation device 980 may be removed at an angle that between 0 degrees and 90 degrees. This may allow portions if not all of the thermal interface material 960 to be reused when the heat-dissipation device 980 is reinstalled/reinserted. This may decrease the amount of time, the cost, and/or complexity for removing the heat-dissipation device 980. For example, not reapplying the thermal interface material 960 may decrease the time, decrease the cost, and/or decrease complexity of the process of removing the heat-dissipation device 980.

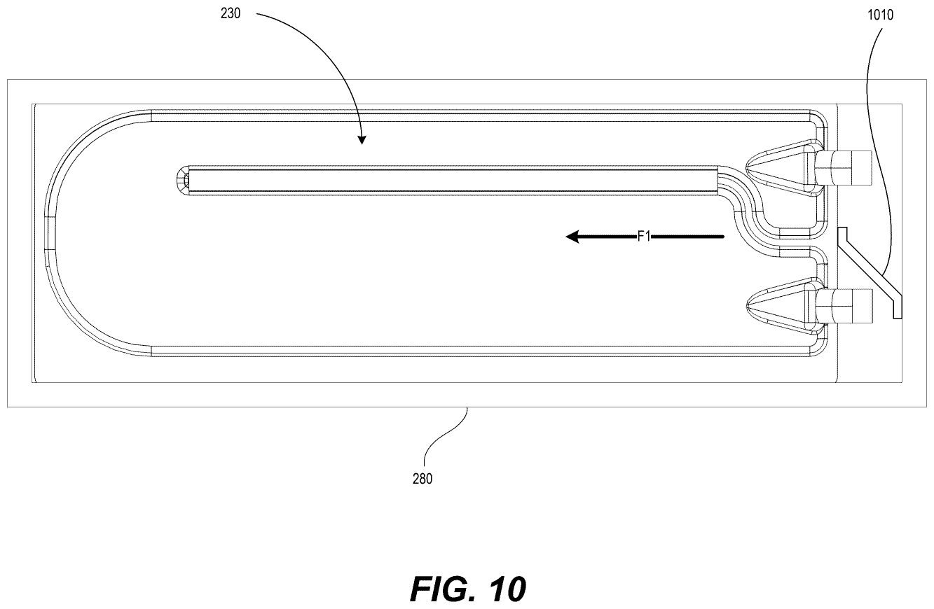

FIG. 10 is a diagram illustrating a top-down view of an example heat-dissipation device 230 (e.g., a heatsink) and an example retention mechanism 740, in accordance with some embodiments of the present disclosure. As discussed above, a computing system 190 may include a heat-dissipation device 230 and one or more heat sources (not illustrated in FIG. 10) located inside an enclosure 280. The enclosure 280 may be a structure that partially or fully encloses one or more components. The heat-dissipation device 230 may dissipate heat that is generated by one or more heat sources (e.g., generated by one or more processing devices). The heat-dissipation device 230 may be in an inserted configuration/position. The heat-dissipation device 230 may be inserted into the enclosure 280 using alignment mechanisms/features (e.g., tabs, protrusions, rails, grooves, wheels, etc.).

As illustrated in FIG. 10, a retention mechanism 1010 may maintain the heat-dissipation device 230 in an inserted configuration/position. For example, the retention mechanism 1010 may be a leaf spring that may apply a force (e.g., a retention force) to or on the heat-dissipation device 230. The retention force may push the heat-dissipation device 230 towards the left, preventing the heat-dissipation device 230 from moving towards the right (e.g., from becoming loose). Although a leaf spring is illustrated as an example of a retention mechanism 1010, other types of devices, components, structures may be used in a retention mechanism. For example, other types of springs, tabs, flexible members, etc., may be used to apply a retention force on the heat-dissipation device 230 to maintain the heat-dissipation device 230 in an inserted configuration/position.

In one embodiment, the retention force may be applied along a single dimension of the heat-dissipation device 230. For example, the top-down view of the heat-dissipation device may include an X-axis (going from the left to the right of FIG. 10), a Y-axis (going from the top to the bottom of FIG. 10), and a Z-axis (going down into or coming upwards out of FIG. 10). As illustrated by the arrow F1, the retention mechanism 1010 applies a retention force to the heat-dissipation device 230 along the X-axis (e.g., along the arrow F1). Other types of retention mechanisms may include components (e.g., screws, clamps, etc.) that apply retention forces in multiple axis or dimensions. For example, other types of retention mechanisms may use multiple clamps/screws (e.g., four clamps/screws) to maintain a heat-dissipation device in an installed/inserted configuration.

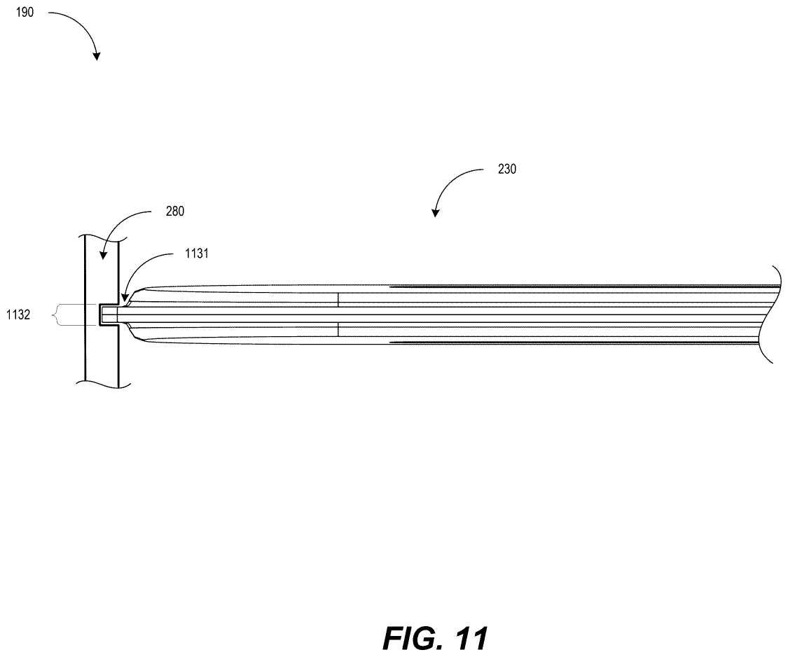

FIG. 11 is a side view of a portion of an example heat-dissipation device 230 (e.g., a heatsink), in accordance with some embodiments of the present disclosure. As discussed above, computing system 190 may include a heat-dissipation device 230 and one or more heat sources (not illustrated in FIG. 10) located inside an enclosure 280. The enclosure 280 may be a structure that partially or fully encloses one or more components. The heat-dissipation device 230 may dissipate heat that is generated by one or more heat sources (e.g., generated by one or more processing devices).

The heat-dissipation device 230 may be in an inserted configuration/position in FIG. 11. As discussed above, the heat-dissipation device 230 may be inserted into the enclosure 280 using alignment mechanisms/features (e.g., tabs, protrusions, rails, grooves, wheels, etc.). The heat-dissipation device 230 includes alignment feature 1131 (e.g., a tab, a protrusion, an edge, etc.). The alignment feature 1131 interfaces with the alignment feature 1132 (e.g., a rail, groove, slot, opening, etc.) of the enclosure 280. The alignment feature 1131 will fit and/or move (e.g., slide) within the alignment feature 1132. For example, alignment features 1131 of the heat-dissipation device 230 may be inserted into alignment features 1132 of the enclosure 280 to guide or the insertion/removal of the heat-dissipation device 230. The alignment features 1131 and 1132 allow the heat-dissipation device to be removed inline with plane C and plane D illustrated in FIGS. 6 and 7.

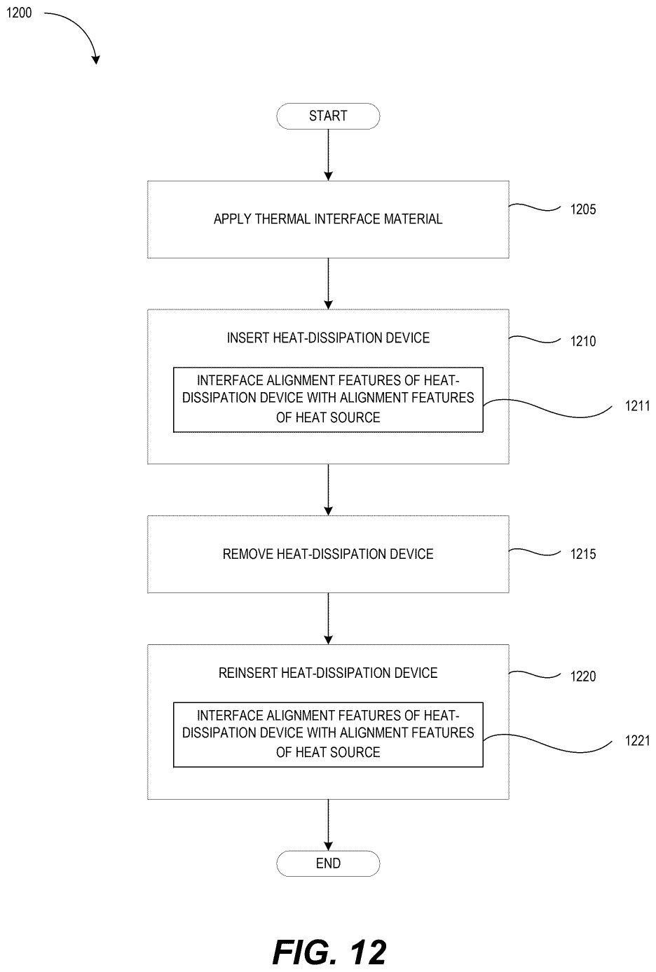

FIG. 12 is a flow diagram of a method 1200 for installing a heat-dissipation device, in accordance with one or more embodiments of the present disclosure. Method 1200 may be performed by during a manufacturing process and/or during a service operation (e.g., a repair or maintenance operation).

With reference to FIG. 12, method 1200 illustrates example functions used by various embodiments. Although specific function blocks (“blocks”) are disclosed in method 1200, such blocks are examples. That is, embodiments are well suited to performing various other blocks or variations of the blocks recited in method 1200. It is appreciated that the blocks in method 1200 may be performed in an order different than presented, and that not all of the blocks in method 1200 may be performed, and other blocks (which may not be included in FIG. 12) may be performed between the blocks illustrated in FIG. 12.

The method 1200 begins at block 1205 where the method 1200 includes applying thermal interface material (e.g., thermal grease, a thermal pad, etc.). For example, thermal interface material may be applied to a surface of a heat source (e.g., the lid of a processing device, a processing die, etc.). The thermal interface material may also be applied to a surface of the heat-dissipation device (e.g., the surface of the heat-dissipation device that will contact the surface of the heat source or absorb heat from the heat source).

At block 1210, the method 1200 includes inserting the heat-dissipation device into an enclosure (or other structure) where the heat source is located. For example, the heat-dissipation device may be inserted into a chassis/frame where the heat source is located. Inserting the heat-dissipation device may also be referred to as installing the heat-dissipation device. A retention mechanism may also be activated, actuated, installed, etc., to maintain the heat-dissipation device in an inserted configuration. Inserting the heat-dissipation device may also include block 1211. At block 1211, the method 1200 includes interfacing alignment features of the heat-dissipation device with alignment features of the heat source. For example, tabs of the heat-dissipation device may be interfaced with grooves/slots in the heat source.

At block 1215, the method includes removing the heat-dissipation device from the enclosure. For example, the alignment features may be used to guide the removal (and insertion) of the heat-dissipation device. The retention mechanism may be deactivated/removed, etc., to allow removal of the heat-dissipation device. As discussed above, the heat-dissipation device may have a wedge-shaped cross section that may form an angle. The heat-dissipation device may be removed along a plane that bisects the angle of the wedge-shaped cross section. Also as discussed above, removing the heat-dissipation device along the plane that bisects the angle of the wedge-shaped cross section may reduce the amount of shear or shear force on the thermal interface material. This allows some or all of the thermal interface material to be reusable.

At block 1220, the method 1200 includes reinserting the heat-dissipation device into the enclosure (or other structure). The retention mechanism may also be activated, actuated, installed, etc., to maintain the heat-dissipation device in an inserted configuration. Reinserting the heat-dissipation device may also include block 1221. At block 1221, the method 1200 includes interfacing alignment features of the heat-dissipation device with alignment features of the heat source. In one embodiment, because the thermal interface material is reused/reusable, additional thermal interface material does not need to be applied when the heat-dissipation device is reinserted. This may reduce the cost, complexity, and time for removing and reinserting the heat-dissipation device.

Although embodiment, examples, and/or implementations of the disclosure are described, persons of ordinary skill in the art will appreciate that the description and figures illustrate rather than limit the invention and that in general the figures may not be drawn to scale for clarity of presentation. In addition, although certain angles (e.g., angles for the wedge-shaped cross section of a heat-dissipation device) are described herein, other suitable angles may be used in other embodiments. For example, the angle of the wedge-shaped cross section may be based on one or more of, the amount of retention force applied by the retention mechanism, the type of thermal interface material, mechanical properties of the thermal interface material, etc. Moreover, although certain shapes, configurations, geometries, etc., are illustrated for a heat-dissipation device (e.g., a rectangular shaped heat-dissipation device), any appropriate share, configuration, geometry, etc., can be used in other embodiments. For example, a circular or triangular shaped heat-dissipation device may be used. Furthermore, the heat-dissipation devices described herein may be used in any appropriate device, including but not limited to, desktop computers, server computers, gaming devices, networking devices, communication devices, electronic devices, etc.

Unless specifically stated otherwise, terms such as “inserting,” “installing,” “attaching,” “removing,” “uninstalling,” “detaching,” “applying,” “reapplying,” “activating,” or the like, refer to actions and processes performed or implemented by computing devices that manipulates and transforms data represented as physical (electronic) quantities within the computing device's registers and memories into other data similarly represented as physical quantities within the computing device memories or registers or other such information storage, transmission or display devices. Also, the terms “first,” “second,” “third,” “fourth,” etc., as used herein are meant as labels to distinguish among different elements and may not necessarily have an ordinal meaning according to their numerical designation.

Examples described herein also relate to an apparatus for performing the operations described herein. This apparatus may be specially constructed for the required purposes, or it may comprise a general-purpose computing device selectively programmed by a computer program stored in the computing device. Such a computer program may be stored in a computer-readable non-transitory storage medium.

The methods and illustrative examples described herein are not inherently related to any particular computer or other apparatus. Various general-purpose systems may be used in accordance with the teachings described herein, or it may prove convenient to construct more specialized apparatus to perform the required method steps. The re structure for a variety of these systems will appear as set forth in the description above.

The above description is intended to be illustrative, and not restrictive. Although the present disclosure has been described with references to specific illustrative examples, it will be recognized that the present disclosure is not limited to the examples described. The scope of the disclosure should be determined with reference to the following claims, along with the full scope of equivalents to which the claims are entitled.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. An apparatus comprising:
an electronic device comprising a first surface;
a heat-dissipation device comprising a second surface and a third surface, wherein an angle between the second surface and the third surface comprises a non-zero angle and wherein the heat-dissipation device is removable from the apparatus; and
a thermal interface material disposed between the first surface and the second surface.

2. The apparatus of claim 1, wherein the heat-dissipation device comprises a wedge-shaped cross section formed by the second surface and the third surface and wherein at least a portion of the thermal interface material is reusable after removal of the heat-dissipation device.

3. The apparatus of claim 1, further comprising:
a second electronic device comprising a fourth surface; and
a second thermal interface material disposed between the third surface and the fourth surface, wherein the electronic device generates heat when in operation and wherein the second electronic device generates heat when in operation.

4. The apparatus of claim 3, wherein a second angle between the first surface and the fourth surface is within a threshold of the non-zero angle.

5. The apparatus of claim 1, further comprising:
an enclosure, wherein the electronic device, the heat-dissipation device, and the thermal interface material are disposed within the enclosure.

6. The apparatus of claim 1, further comprising:
a first set of alignment mechanisms configured to interface with a second set of alignment mechanisms of the heat-dissipation device, wherein the first set of alignment mechanisms and second set of alignment mechanisms guide the heat-dissipation device during insertion and removal.

7. The apparatus of claim 6, wherein the first set of alignment mechanisms and the second set of alignment mechanisms are positioned guide the heat-dissipation device along a plane that bisects the non-zero angle.

8. The apparatus of claim 7, wherein the heat-dissipation device reduces an amount of lateral shear force on the thermal interface material during removal of the heat-dissipation device when compared to removing the heat-dissipation device along a second plane that is parallel to the second surface.

9. The apparatus of claim 1, further comprising:
a retention mechanism configured to maintain the heat-dissipation device in an inserted configuration, wherein the retention mechanism causes a retention force to be applied to the heat-dissipation device along a single dimension of the heat-dissipation device.

10. The apparatus of claim 1, wherein at least a portion of the thermal interface material is reusable after removal of the heat-dissipation device.

11. A method, comprising:
applying a thermal interface material to one or more of a first surface of an electronic device, a second surface of a heat-dissipation device, and a third surface of the heat-dissipation device, wherein an angle between the second surface and the third surface comprises a non-zero angle;
inserting the heat-dissipation device into an apparatus such that first surface of the heat-dissipation device is in planar alignment with the first surface of the electronic device; and
removing the heat-dissipation device from the apparatus.

12. The method of claim 11, wherein the heat-dissipation device comprises a wedge-shaped cross section formed by the second surface and the third surface and wherein at least a portion of the thermal interface material is reusable after removal of the heat-dissipation device.

13. The method of claim 11, wherein the third surface of the heat-dissipation device is in planar alignment with a fourth surface of a second electronic device.

14. The method of claim 13, wherein a second angle between the first surface and the fourth surface is within a threshold of the non-zero angle.

15. The method of claim 11, wherein the heat-dissipation device is inserted into the apparatus and removed from the apparatus based on a first set of alignment mechanisms located on an enclosure and a second set of alignment mechanisms located on the heat-dissipation device.

16. The method of claim 15, wherein the first set of alignment mechanisms and the second set of alignment mechanisms are positioned guide the heat-dissipation device along a plane that bisects the non-zero angle.

17. The method of claim 16, wherein the heat-dissipation device reduces an amount of lateral shear force on the thermal interface material during removal of the heat-dissipation device when compared to removing the heat-dissipation device along a second plane that is parallel to the second surface.

18. The method of claim 11, further comprising:
activating a retention mechanism configured to maintain the heat-dissipation device in an inserted configuration.

19. The method of claim 18, wherein the retention mechanism causes a retention force to be applied to the heat-dissipation device along a single dimension of the heat-dissipation device.

20. A heatsink, comprising:
a first surface; and
a second surface, wherein an angle between the first surface and the second surface comprises a non-zero angle, wherein the heatsink is removable from an enclosure; and
a first set of alignment features configured to interface with a second set of alignment features of the enclosure, wherein at least a portion of a thermal interface material is reusable after the heatsink is removed from the enclosure along a plane that bisects the non-zero angle.
